(19) United States
(12) Patent Application Publication
(10) Pub. No.: US 2016/0148804 A1
(43) Pub. Date: May 26, 2016

(54) METHOD FOR PRODUCING A THIN FILM TRANSISTOR

(71) Applicant: NATIONAL SUN YAT-SEN UNIVERSITY, Kaohsiung (TW)

(72) Inventors: Ting-Chang Chang, Kaohsiung (TW); Ming-Yen Tsai, Kaohsiung (TW); Hua-Mao Chen, Kaohsiung (TW); Tian-Yu Hsieh, Kaohsiung (TW)

(21) Appl. No.: 14/561,884

(22) Filed: Dec. 5, 2014

(30) Foreign Application Priority Data
Nov. 21, 2014 (TW) 103140499

(51) Int. Cl. H01L 21/02; H01L 29/66

(52) U.S. Cl. CPC H01L 21/02101; H01L 29/66765

(57) ABSTRACT

A method for producing a thin film transistor includes forming a transistor prototype on a substrate, with the transistor prototype including a face having a to-be-treated portion. The to-be-treated portion of the transistor prototype is exposed in an environment full of a supercritical fluid. The supercritical fluid conducts a surface treatment on the to-be-treated portion of the transistor prototype to form a thin film transistor. The method can solve the problem of too many defects of the thin film transistor resulting from a low-temperature process.

### BACKGROUND OF THE INVENTION

1. Field of the Invention

The present invention relates to a method for producing a thin film transistor and, more particularly, to a method for producing a thin film transistor suitable for a flexible substrate.

2. Description of the Related Art

Due to progress of the semiconductor technology, thin film transistors (TFTs) have gradually been developed as electronic switches and have widely been used in various electronic devices. Taking a flat display as an example, amorphous/poly silicon semiconductor can be used as an active layer of a thin film transistor so as to use the thin film transistor as a charging/discharging switch element for a charge storage capacitor for controlling pixels.

A conventional method for producing a thin film transistor generally includes forming a gate on a hard substrate, forming a gate insulator on the gate, forming an active layer on the gate insulator, and forming a source contact layer and a drain contact layer on two sides of the active layer. Then, a passivation layer is formed on the two sides of the active layer, the source contact layer, and the drain contact layer to achieve the protection effect of the passage on the atmosphere. Since the sizes of the electronic devices become smaller and smaller, the material for the substrate of the thin film transistor changes from hard to flexible to fit in the limited spaces of the electronic devices.

In the conventional method for producing a thin film transistor, the processing temperature for forming the gate insulator is about 300° C., an example of which is disclosed by Paul G. Carey, Patrick M. Smith, Steven D. Theiss, and Paul Wickboldt (“Polysilicon thin film transistors fabricated on low temperature plastic substrates”, pp. 1946, American Vacuum Society, 1999). The processing of a flexible substrate is generally a low temperature process carried out at a temperature below 200° C. (such as 110° C.). However, the gate insulator will have many defects if the processing temperature for producing the thin film transistor is below 200° C., leading to electricity leakage of the gate insulator. Furthermore, the protection effect of the passage on the atmosphere cannot be achieved if the processing temperature for producing the thin film transistor is not high enough, leading to poor electrical performances and poor reliability of the thin film transistor.

Thus, it is necessary to solve the above drawbacks in the prior art to meet practical needs, thereby increasing the utility.

### SUMMARY OF THE INVENTION

An objective of the present invention is to provide a method for producing a thin film transistor, wherein the thin film transistor can be produced at a temperature suitable for a flexible substrate while passivating the defects of the thin film transistor.

A method for producing a thin film transistor according to the present invention includes forming a transistor prototype on a substrate, with the transistor prototype including a face having a to-be-treated portion. The to-be-treated portion of the transistor prototype is exposed in an environment full of a supercritical fluid. The supercritical fluid conducts a surface treatment on the to-be-treated portion of the transistor prototype to form a thin film transistor.

The supercritical fluid can contain a cosolvent.

The cosolvent can be a liquid containing hydroxyl.

The can be water, alcohol, or oxalic acid.

The to-be-treated portion of the transistor prototype can be irradiated with ultraviolet light during the surface treatment by the supercritical fluid.

The thin film transistor can have a coplanar, inverted coplanar, staggered, or inverted staggered structure.

In an example, the transistor prototype includes a gate formed on the substrate, and wherein a gate insulator is formed on the gate and the substrate and forms the to-be-treated portion of the transistor prototype.

In another example, the transistor prototype includes a gate formed on the substrate, a gate insulator is formed on the gate and the substrate, and an active layer is formed on the gate insulator and forms the to-be-treated portion of the transistor prototype.

In a further example the transistor prototype includes a gate formed on the substrate, a gate insulator is formed on the gate and the substrate, an active layer is formed on the gate insulator, a source and a drain are formed on two sides of the active layer, a passivation layer is formed on the active layer, the source, and the drain, and the passivation layer forms the to-be-treated portion of the transistor prototype.

The transistor prototype can be placed in a reaction chamber filled with the supercritical fluid during the surface treatment by the supercritical fluid.

A ratio of a volume of the cosolvent to a volume of the reaction chamber can be about 1:100.

The reaction chamber can have a temperature of 100-199° C. and a pressure of 1500-3000 psi.

The supercritical fluid can contain carbon dioxide.

The substrate can be a flexible substrate.

By the method for producing a thin film transistor according to the present invention, during the supercritical processing procedure on the thin film surface of the to-be-treated portion (the gate insulator, the active layer, and/or the passivation layer) of the thin film transistor, the hydroxyl in the cosolvent is used to repair the broken bonds at the thin film surface to thereby passivate the surface defects and to oxidize the thin film. Furthermore, UV irradiation can be used to break the weak bonds at the thin film surface. The broken weak bonds can be repaired by the hydroxyl in the cosolvent to increase the compactness of the thin film surface. Thus, the bonding of the material deposited on the thin film surface is tighter to further reduce the interface defects. The effects of reducing the sub-threshold swing, increasing the conduction current, and increasing the element reliability can be achieved.

The present invention will become clearer in light of the following detailed description of illustrative embodiments of this invention described in connection with the drawings.

### BRIEF DESCRIPTION OF THE DRAWINGS

The illustrative embodiments may best be described by reference to the accompanying drawings where:

FIG. 1 is a block diagram of a method for producing a thin film transistor according to the present invention.

FIG. 2a is a diagrammatic view of an example of a transistor prototype used in the method for producing a thin film transistor according to the present invention.

FIG. 2b is a diagrammatic view of another example of the transistor prototype used in the method for producing a thin film transistor according to the present invention.

FIG. 2c is a diagrammatic view of a further example of the transistor prototype used in the method for producing a thin film transistor according to the present invention.

FIG. 3a is a drain current-gate voltage diagram of a product produced by the method for producing a thin film transistor according to the present invention.

FIG. 3b is another drain current-gate voltage diagram of a product produced by the method for producing a thin film transistor according to the present invention, wherein the Y-axis (drain current) in FIG. 3a is converted into a linear axis.

### DETAILED DESCRIPTION OF THE INVENTION

The term “supercritical fluid” referred to herein means a substance at a temperature higher than its critical temperature and at a pressure higher than its critical pressure and, thus, exhibits a supercritical fluidic state, such as possessing the penetrability of a gas and the viscosity of a liquid, which can be appreciated by one having ordinary skill in the art.

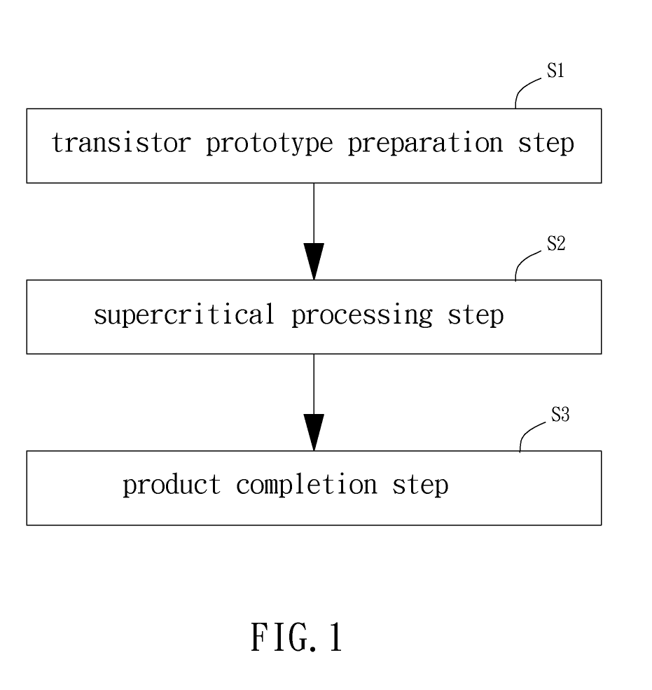

With reference to FIG. 1, a method for producing a thin film transistor according to the present invention includes a transistor prototype preparation step S1, a supercritical processing step S2, and a product completion step S3.

Still referring to FIG. 1, in the transistor prototype preparation step S1 a transistor prototype is formed on a substrate F. The transistor prototype includes a face having at least one to-be-treated portion. The transistor prototype can be a semi-product of a thin film transistor having a coplanar, inverted coplanar, staggered, or inverted staggered structure. However, the present invention is not limited to such structures. In this embodiment, the substrate F is a flexible substrate, such as a thin glass substrate, a thin metal foil substrate, or a plastic substrate. However, the substrate F can be a hard substrate. The transistor prototype of an inverted staggered structure will be set forth as a non-restrictive example.

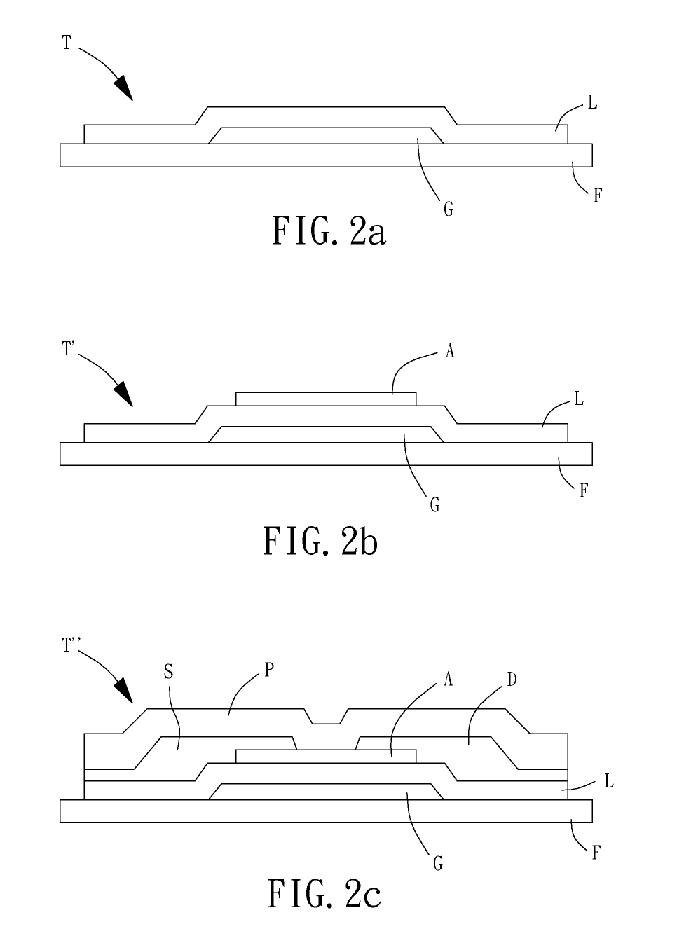

In an example shown in FIG. 2a, a gate G is formed on the substrate F, and a gate insulator L is formed on the gate G and the substrate F to form the transistor prototype T, wherein the gate insulator L is used as the to-be-treated portion. In another example shown in FIG. 2b, in addition to formation of the gate G and the gate insulator L on the substrate F, an active layer A is formed on the gate insulator L to form the transistor prototype T′, wherein the gate G and/or the active layer A are/is used as the to-be-treated portion. In a further example shown in FIG. 2c, in addition to formation of the gate G, the gate insulator L, and the active layer A on the substrate F, a source S and a drain D are formed on two sides of the active layer A, and a passivation layer P is formed on the active layer A, the source S, and the drain D to form the transistor prototype T″, wherein at least one of the gate G, the active layer A, and the passivation layer P forms the to-be-treated portion of the transistor prototype. However, the present invention is not limited to these examples.

Still referring to FIGS. 2a, 2b, and 2c, preparation of the transistor prototype T, T′, T′ can use a conventional semiconductor process, such as using a conventional plastic flexible substrate as the substrate F. Next, a layer of first metal material is deposited on the substrate F, and first yellow light lithography is conducted on the layer of first metal material to form the gate G by etching. Then, an insulating material (such as silicon dioxide, SiO2) is deposited on the gate G and the substrate F to serve as the gate insulator L. Next, an oxide (such as zinc oxide, ZnO) is deposited on the gate insulator L, and second yellow light lithography is conducted on the oxide to form the active layer A by etching. Then, a layer of second metal material is deposited on the active layer A and the gate insulator L, and third yellow light lithography is conducted on the layer of second metal material to form the source S and the drain D by etching. Next, an insulating layer is deposited on the active layer A, the source S, and the drain D and serves as the passivation layer P. However, the present invention is not limited to this example. The supercritical processing step S2 is conducted subsequently.

Still referring to FIG. 1, in the supercritical processing step S2 the to-be-treated portion of the transistor prototype is exposed in an environment full of a supercritical fluid. The supercritical fluid conducts a surface treatment on the to-be-treated portion of the transistor prototype to form a supercritical product for producing a thin film transistor. In this embodiment, as can be seen from FIG. 2a, the temperature in a reaction chamber (not shown) is adjusted (such as adjusted to be below 200° C., e.g., 100-199° C.), and the pressure in the reaction chamber is adjusted (such as 1500-3000 psi), such that the temperature and the pressure are suitable for processing procedures for a flexible substrate. Then, the transistor prototype T is placed in the reaction chamber, and the supercritical fluid (such as carbon dioxide in the supercritical state) is filled into the reaction chamber. The supercritical fluid can contain a cosolvent, such as water, alcohol, or oxalic acid that contains hydroxyl. The cosolvent and the supercritical fluid can be mixed with each other in another chamber before entering the reaction chamber. A ratio of a volume of the cosolvent to a volume of the reaction chamber is about 1:100. As an example, the volume of the reaction chamber can be 200 ml, and the volume of the cosolvent can be about 1-2 ml. During the surface treatment, the to-be-treated portion of the transistor prototype T is exposed in the environment full of the supercritical fluid containing the cosolvent, such that the supercritical fluid can conduct the surface treatment on the to-be-treated portion of the transistor prototype T. The hydroxyl in the cosolvent repairs broken bonds on the surface of the transistor prototype to passivate the surface defects and to oxidize the thin film, forming the supercritical product and reducing the interface defects.

Furthermore, during the above supercritical processing procedure, an ultraviolet light can be used to irradiate the transistor prototype. In this embodiment, an ultraviolet light (such as having a light intensity of 30,000 lux and a power of 500 W, and the irradiation time is 5-60 minutes) is used to irradiate the to-be-treated portion of the transistor prototype during the supercritical processing procedure. Since the ultraviolet light can break the weak bonds on the surface of the to-be-treated portion (such as the thin film surface of the gate insulator L shown in FIG. 2a) of the transistor prototype, the broken weak bonds can be repaired by the hydroxyl in the cosolvent to increase the compactness of the thin film surface. Thus, the bonding of the material deposited on the thin film surface is tighter to further reduce the interface defects.

In addition to the gate insulator L of the transistor prototype T (see FIG. 2a), the above supercritical processing procedure and the above irradiation procedure can be carried out on the active layer A of the transistor prototype T′ (see FIG. 2b) or on the passivation layer P of the transistor prototype T″ (see FIG. 2c). The thin film undergoing the supercritical processing procedure and the irradiation procedure can be the gate insulator L, the active layer A, and/or the passivation layer P of the transistor prototype. However, the present invention is not limited to these examples.

In an example of using zinc oxide (ZnO) as the active layer A subjected to the supercritical processing procedure and the irradiation procedure, the broken bond Zn— of zinc oxide is repaired by the hydroxyl (OH) of the cosolvent and turns into Zn—OH. The bonds of the last two Zn—OH HO—Zn can be dehydrated in the supercritical environment into a perfect lattice of Zn—O—Zn. Next, the product completion step S3 is optionally carried out according to the structure of the supercritical product. Namely, the product completion step S3 is not necessary if the supercritical product possesses the complete structure of the thin film transistor. Otherwise, the remaining structure of the thin film transistor must be produced from the supercritical product, which will be described hereinafter.

Still referring to FIG. 1, in the product completion step S3 the thin film transistor is produced from the supercritical product (the semi-product of the transistor), such that the gate G is formed on the substrate F, the gate insulator L is formed on the gate G and the substrate F, the active layer A is formed on the gate insulator L, the source S and the drain D are formed on two sides of the active layer A, and the passivation layer P is formed on the active layer A, the source S, and the drain D. In this embodiment, if only the gate G and the gate insulator L of the transistor prototype are formed on the substrate F (see FIG. 2a), the active layer A, the source S, the drain D, and the passivation layer P can be formed on the gate insulator L of the supercritical product to form the thin film transistor. In another example of the transistor prototype in which the gate G the gate insulator L, and the active layer A are formed on the substrate F (see FIG. 2b), the source S, the drain D, and the passivation layer P can be formed on the gate insulator L of the supercritical product to form the thin film transistor. In a further example of the transistor prototype in which the gate G, the gate insulator L, the active layer A, the source S, the drain D, and the passivation layer P are formed on the substrate F (see FIG. 2c), the subsequent transistor processing procedures of the supercritical product can optionally be carried out according to needs. The structure of the thin film transistor can be coplanar, inverted coplanar, staggered, or inverted staggered. However, the present invention is not limited to these examples.

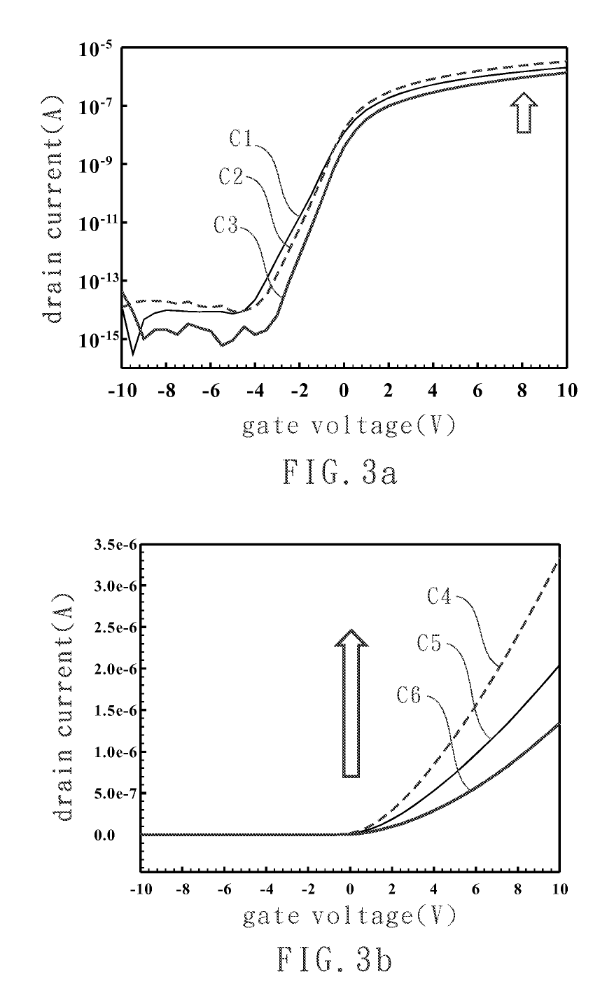

FIG. 3a is a drain current-gate voltage diagram of a product produced by the method for producing a thin film transistor according to the present invention. C1 is the drain current-gate voltage diagram of a thin film transistor without the supercritical processing procedure during the manufacturing process. C3 is the drain current-gate voltage diagram of a thin film transistor subjected to the surface treatment by the supercritical fluid during the manufacturing process. C2 is the drain current-gate voltage diagram of a thin film transistor subjected to the supercritical processing procedure, the UV irradiation, and addition of cosolvent during the manufacturing process. The sub-threshold swing of C1 is 0.57, and the sub-threshold swing of C2 and C3 can be reduced to 0.49.

FIG. 3b is another drain current-gate voltage diagram of a product produced by the method for producing a thin film transistor according to the present invention, wherein the Y-axis (drain current) in FIG. 3a is converted into a linear axis. C4 is the drain current-gate voltage diagram of a thin film transistor subjected to the supercritical processing procedure, the UV irradiation, and addition of cosolvent during the manufacturing process. C5 is the drain current-gate voltage diagram of a thin film transistor without the supercritical processing procedure during the manufacturing process. C6 is the drain current-gate voltage diagram of a thin film transistor subjected to the surface treatment by the supercritical fluid during the manufacturing process. As can be seen from the drawing, if the thin film transistor has been subjected to UV irradiation and if cosolvent has been added, the conduction current can greatly be increased. Therefore, the method for producing a thin film transistor according to the present invention can be conducted at a low temperature (below 200° C.) while improving the electricity leakage problem resulting from the interface defects. Thus, the electrical performances (such as the conduction current) of the thin film transistor and the reliability of the thin film transistor can be increased.

By the above technical solutions, the main features of the method for producing a thin film transistor according to the present invention are that, during the manufacturing process, the surface treatment can be conducted on the thin film surface of the to-be-treated portion (the gate insulator L, the active layer A, and/or the passivation layer P) of the thin film transistor. By exposing the to-be-treated portion of the transistor prototype in the environment full of the supercritical fluid and using the hydroxyl in the cosolvent to repair the broken bonds at the thin film surface, the surface defects are passivated and the thin film is oxidized. UV irradiation can be used during the supercritical processing procedure. The UV light can break the weak bonds at the thin film surface. The broken weak bonds can be repaired by the hydroxyl in the cosolvent to increase the compactness of the thin film surface. Thus, the bonding of the material deposited on the thin film surface is tighter to further reduce the interface defects. The effects of reducing the sub-threshold swing, increasing the conduction current, and increasing the element reliability can be achieved.

Furthermore, the method for producing a thin film transistor according to the present invention is compatible with current semiconductor processes. The supercritical processing procedure can be conducted after formation of the gate insulator L, the active layer A, and/or the passivation layer P to repair the thin film surface of the gate insulator L, the active layer A, and/or the passivation layer P, Thus, the bonding of the material deposited on the thin film surface is tighter to further reduce the interface defects.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

1. A method for producing a thin film transistor, comprising:
forming a transistor prototype on a substrate, with the transistor prototype including a face having a to-be-treated portion; and
exposing the to-be-treated portion of the transistor prototype in an environment full of a supercritical fluid, with the supercritical fluid conducting a surface treatment on the to-be-treated portion of the transistor prototype to form a thin film transistor,
wherein the to-be-treated portion of the transistor prototype is irradiated with ultraviolet light during the surface treatment by the supercritical fluid,
wherein the supercritical fluid contains a cosolvent,
wherein the transistor prototype is placed in a reaction chamber filled with the supercritical fluid during the surface treatment by the supercritical fluid, and
wherein a ratio of a volume of the cosolvent to a volume of the reaction chamber is 1:100.

2. (canceled)

3. The method for producing a thin film transistor as claimed in claim 1, wherein the cosolvent is a liquid containing hydroxyl.

4. The method for producing a thin film transistor as claimed in claim 3, wherein the cosolvent is water, alcohol, or oxalic acid.

5. (canceled)

6. The method for producing a thin film transistor as claimed in claim 1, wherein the thin film transistor has a coplanar, inverted coplanar, staggered, or inverted staggered structure.

7. The method for producing a thin film transistor as claimed in claim 1, wherein the transistor prototype includes a gate formed on the substrate, and wherein a gate insulator is formed on the gate and the substrate and forms the to-be-treated portion of the transistor prototype.

8. The method for producing a thin film transistor as claimed in claim 1, wherein:
the transistor prototype includes a gate formed on the substrate, a gate insulator is formed on the gate and the substrate, and an active layer is formed on the gate insulator and forms the to-be-treated portion of the transistor prototype.

9. The method for producing a thin film transistor as claimed in claim 1, wherein:
the transistor prototype includes a gate formed on the substrate, a gate insulator is formed on the gate and the substrate, an active layer is formed on the gate insulator, a source and a drain are formed on two sides of the active layer, a passivation layer is formed on the active layer, the source, and the drain, and the passivation layer forms the to-be-treated portion of the transistor prototype.

10. (canceled)

11. (canceled)

12. (canceled)

13. The method for producing a thin film transistor as claimed in claim 1, wherein the reaction chamber has a temperature of 100-199° C. and a pressure of 1500-3000 psi.

14. The method for producing a thin film transistor as claimed in claim 1, wherein the supercritical fluid contains carbon dioxide.

15. The method for producing a thin film transistor as claimed in claim 1, wherein the substrate is a flexible substrate.
